(19) United States
(12) Patent Application Publication
(10) Pub. No.: US 2020/0126769 A1
(43) Pub. Date: Apr. 23, 2020

(54) PLASMA ASHING OF COATED SUBSTRATES

(71) Applicant: HZO, Inc.

(72) Inventors: Robert Askin, III, Cary, NC (US); Sean Clancy, Apex, NC (US); John Janik, Raleigh, NC (US); Benjamin Lawrence, Salt Lake City, UT (US)

(21) Appl. No.: 16/662,014

(22) Filed: Oct. 23, 2019

Related U.S. Application Data
(60) Provisional application No. 62/749,273, filed on Oct. 23, 2018.

(51) Int. Cl. H01J 37/32; H05K 3/28; B08B 7/00

(52) U.S. Cl. CPC H01J 37/32568; H05K 3/288; B08B 7/0035; H05K 2203/1121; H01J 2237/335; H01J 2237/3342; H05K 2203/095; H01J 2237/002

(57) ABSTRACT

A system for plasma etching or ashing a coating on a substrate includes a plasma chamber, a second electrode, a plasma source coupled to the plasma chamber, a substrate including a coating, and a plasma mask including at least one aperture. The plasma chamber includes a first electrode. The plasma mask is configured to cover the substrate while exposing selected surfaces of the substrate and coating through the at least one aperture. The first electrode and the second electrode are configured to initiate and maintain a plasma within the plasma chamber. The plasma source includes a gas.

### RELATED APPLICATIONS

This application claims the benefit of U.S. Provisional Patent Application No. 62/749,273, filed Oct. 23, 2018, which is incorporated herein by reference in its entirety.

### BACKGROUND

This disclosure relates generally to selective removal of protective coatings from printed circuit boards (PCB) or printed circuit board assemblies (PCBA). More specifically, this disclosure relates to selective removal of protective coatings from PCBAs using plasma. In addition, this disclosure relates to utilizing a plasma mask for selective removal of parylene and parylene-like coatings from PCBAs through plasma ashing.

### SUMMARY

The subject matter of the present application has been developed in response to the present state of the art, and in particular, in response to the problems and disadvantages associated with conventional parylene systems that have not yet been fully solved by currently available techniques. Accordingly, the subject matter of the present application has been developed to provide embodiments of a plasma ashing of parylene coatings that overcome at least some of the shortcomings of prior art techniques.

Disclosed herein is a system for plasma etching or ashing a coating on a substrate. The system includes a plasma chamber, a second electrode, a plasma source coupled to the plasma chamber, a substrate including a coating, and a plasma mask including at least one aperture. The plasma chamber includes a first electrode. The plasma mask is configured to cover the substrate while exposing selected surfaces of the substrate and coating through the at least one aperture. The first electrode and the second electrode are configured to initiate and maintain a plasma within the plasma chamber. The plasma source includes a gas. The preceding subject matter of this paragraph characterizes example 1 of the present disclosure.

The coating is a parylene coating. The system further comprises a power source coupled to the first and second electrodes. The preceding subject matter of this paragraph characterizes example 2 of the present disclosure, wherein example 2 also includes the subject matter according to example 1, above.

The system further includes a cooling mechanism coupled to the plasma chamber. The preceding subject matter of this paragraph characterizes example 3 of the present disclosure, wherein example 3 also includes the subject matter according to any one of examples 1-2, above.

The plasma mask comprises a thermal interface material. The preceding subject matter of this paragraph characterizes example 4 of the present disclosure, wherein example 4 also includes the subject matter according to any one of examples 1-3, above.

The plasma mask comprises a bevel at the at least one aperture. The preceding subject matter of this paragraph characterizes example 5 of the present disclosure, wherein example 5 also includes the subject matter according to any one of examples 1-4, above.

The plasma mask is mechanically coupled to the substrate. The preceding subject matter of this paragraph characterizes example 6 of the present disclosure, wherein example 6 also includes the subject matter according to any one of examples 1-5, above.

At least one of the first electrode and the second electrode comprises at least one cooling channel. The preceding subject matter of this paragraph characterizes example 7 of the present disclosure, wherein example 7 also includes the subject matter according to any one of examples 1-6, above.

At least one of the first electrode and the second electrode comprises a plurality of cooling channels. The preceding subject matter of this paragraph characterizes example 8 of the present disclosure, wherein example 8 also includes the subject matter according to any one of examples 1-7, above.

The plasma mask is either the first electrode or the second electrode. The preceding subject matter of this paragraph characterizes example 9 of the present disclosure, wherein example 9 also includes the subject matter according to any one of examples 1-8, above.

The plasma is initiated and maintained between bi-polar electrodes. The preceding subject matter of this paragraph characterizes example 10 of the present disclosure, wherein example 10 also includes the subject matter according to any one of examples 1-9, above.

The plasma is initiated and maintained between tri-polar electrodes. The preceding subject matter of this paragraph characterizes example 11 of the present disclosure, wherein example 11 also includes the subject matter according to any one of examples 1-10, above.

The plasma mask comprises cooling channels. The preceding subject matter of this paragraph characterizes example 12 of the present disclosure, wherein example 12 also includes the subject matter according to any one of examples 1-11, above.

The plasma chamber further comprises a vacuum. The preceding subject matter of this paragraph characterizes example 13 of the present disclosure, wherein example 13 also includes the subject matter according to any one of examples 1-12, above.

The walls of the plasma chamber are the second electrode. The preceding subject matter of this paragraph characterizes example 14 of the present disclosure, wherein example 14 also includes the subject matter according to any one of examples 1-13, above.

A tray holding the substrate is the first electrode. The preceding subject matter of this paragraph characterizes example 15 of the present disclosure, wherein example 15 also includes the subject matter according to any one of examples 1-14, above.

The at least one aperture has a different aspect ratio than a corresponding component on the substrate. The preceding subject matter of this paragraph characterizes example 16 of the present disclosure, wherein example 16 also includes the subject matter according to any one of examples 1-15, above.

Disclosed herein is a system for plasma etching or ashing a coating on a substrate. The system includes a plasma chamber, a second electrode, a plasma source coupled to the plasma chamber, a substrate including a coating, and a plasma mask including at least one aperture. The plasma chamber includes a first electrode. The plasma mask is configured to cover the substrate while exposing selected surfaces of the substrate and coating through the at least one aperture. The first electrode and the second electrode are configured to initiate and maintain a plasma within the plasma chamber. The plasma source includes a gas. The plasma chamber further comprises a vacuum. The coating is a parylene. A cooling mechanism is coupled to the plasma chamber. The plasma mask comprises a thermal interface material. The preceding subject matter of this paragraph characterizes example 17 of the present disclosure.

Disclosed herein is a method. The method includes providing at least one substrate in a plasma chamber, the substrate including a coating, coupling a plasma mask to the substrate, the plasma mask comprising at least one aperture, generating a plasma within the plasma chamber between a first electrode and a second electrode, and etching or ashing the coating at the at least one aperture with the generated plasma. The preceding subject matter of this paragraph characterizes example 18 of the present disclosure.

The method includes cycling between the etching or ashing and a cooling cycle. The preceding subject matter of this paragraph characterizes example 19 of the present disclosure, wherein example 19 also includes the subject matter according to example 18, above.

Walls of the plasma chamber are the second electrode. The preceding subject matter of this paragraph characterizes example 20 of the present disclosure, wherein example 20 also includes the subject matter according to any one of examples 18-19, above.

The described features, structures, advantages, and/or characteristics of the subject matter of the present disclosure may be combined in any suitable manner in one or more embodiments and/or implementations. In the following description, numerous specific details are provided to impart a thorough understanding of embodiments of the subject matter of the present disclosure. One skilled in the relevant art will recognize that the subject matter of the present disclosure may be practiced without one or more of the specific features, details, components, materials, and/or methods of a particular embodiment or implementation. In other instances, additional features and advantages may be recognized in certain embodiments and/or implementations that may not be present in all embodiments or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific embodiments that are illustrated in the appended drawings. Understanding that these drawings depict only typical embodiments of the subject matter and are not therefore to be considered to be limiting of its scope, the subject matter will be described and explained with additional specificity and detail through the use of the drawings, in which:

FIG. 1 is a schematic diagram of a system for plasma etching or ashing a coating on a substrate, according to one or more embodiments of the present disclosure;

FIG. 2 is a schematic diagram of a system for plasma etching or ashing a coating on a substrate, according to one or more embodiments of the present disclosure;

FIG. 3 is a schematic diagram of substrates and coatings during the etching or ashing, according to one or more embodiments of the present disclosure;

FIG. 4 is a schematic diagram of substrates and coatings during the etching or ashing, according to one or more embodiments of the present disclosure;

FIG. 5 is a schematic diagram of substrates and coatings during the etching or ashing, according to one or more embodiments of the present disclosure;

FIG. 6 is a schematic diagram of substrates and coatings during the etching or ashing, according to one or more embodiments of the present disclosure;

FIG. 7 is a schematic diagram of substrates and coatings during the etching or ashing, according to one or more embodiments of the present disclosure;

FIG. 8 is a schematic diagram of a system for plasma etching or ashing a coating on a substrate, according to one or more embodiments of the present disclosure;

FIG. 9 is a plasma mask, according to one or more embodiments of the present disclosure;

FIG. 10 is a plasma mask, according to one or more embodiments of the present disclosure; and

FIG. 11 is a schematic block diagram of a method, according to one or more embodiments of the present disclosure.

### DETAILED DESCRIPTION

Reference throughout this specification to “one embodiment,” “an embodiment,” or similar language means that a particular feature, structure, or characteristic described in connection with the embodiment is included in at least one embodiment of the present disclosure. Appearances of the phrases “in one embodiment,” “in an embodiment,” and similar language throughout this specification may, but do not necessarily, all refer to the same embodiment. Similarly, the use of the term “implementation” means an implementation having a particular feature, structure, or characteristic described in connection with one or more embodiments of the present disclosure, however, absent an express correlation to indicate otherwise, an implementation may be associated with one or more embodiments.

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

Other aspects, as well as features and advantages of various aspects, of the disclosed subject matter will be apparent to those of ordinary skill in the art through consideration of this disclosure and the appended claims.

Embodiments described herein may be used to remove various types of coatings. Coatings may refer to moisture resistant coatings, parylene, plasma, and ALD created films. Additionally, certain protective layers can be utilized to reduce etching in undesired areas, such as: a parylene coating with a plasma or ALD deposited protective shell, with the shell patterned to avoid those areas of coating (such as a parylene) that will eventually be etched away.

Moisture resistant coatings or films (such as parylene coatings), as well as other coatings or films are used to protect various parts of electronic devices (or substrates) from external influences. Protective coatings, such as parylene, are deposited on parts of the electronic devices in deposition chambers. Parylene, and other protective coatings, are deposited on the parts of electronic devices in various methods and processes. Some of those processes, examples of which are described by U.S. Patent Application Publication Nos. 2009/0263581, 2009/0263641, 2009/0304549, 2010/0203347, 2010/0293812, and 2011/0262740, the entire disclosures of each of which are, by this reference, incorporated herein. The disclosures describe embodiments of equipment and/or processes that may be employed to apply a protective coating.

In many cases, the parylene or other conformal coating is deposited on every exposed surface of the substrates. However, many substrates (substrates refer generally to PCBs, PCBAs, electronic components, electronic devices, etc.) need certain surfaces, components, or areas to be free of the coating. The coating may interfere with the function of the components. These may include electrical connections, contact points, USB connections, etc.

In many cases, to keep areas coating-free, masks are placed on the substrate prior to depositing the coating. Often, many parts of a single surface need to be coating free. This requires multiple applications of masking materials to the component or part, which takes time and costs money. Each individual masking of each surface of the component or item must then be removed, requiring additional time and money. The masking material may not always adequately adhere to the item or component. In this case, the coating must be removed. The masking material may be adhered so well to the item or component that it may require complex processes to remove the masking material or residual adhesion materials. The coating may damage the masking material or otherwise render the masking material unsuitable for further use. Often the masking material is ruined by the removal process, which also renders the making material unsuitable for further use. Embodiments described herein reduce time and money of traditional masking and coating removal.

Embodiments described herein use plasma and plasma masks to remove coatings from desired locations. Disclosed herein is a system for plasma etching or ashing a coating on a substrate. The system includes a plasma chamber, a second electrode, a plasma source coupled to the plasma chamber, a substrate including a coating, and a plasma mask including at least one aperture. The plasma chamber includes a first electrode. The plasma mask is configured to cover the substrate while exposing selected surfaces of the substrate and coating through the at least one aperture. The first electrode and the second electrode are configured to initiate and maintain a plasma within the plasma chamber. The plasma source includes a gas.

In some embodiments, the coating is a parylene coating. In some embodiments, the system further comprises a power source coupled to the first and second electrodes. In some embodiments, the system further includes a cooling mechanism coupled to the plasma chamber.

In some embodiments, the plasma mask comprises a thermal interface material. In some embodiments, the plasma mask comprises a bevel at the at least one aperture. In some embodiments, the plasma mask is mechanically coupled to the substrate.

In some embodiments, at least one of the first electrode and the second electrode comprises at least one cooling channel. In some embodiments, at least one of the first electrode and the second electrode comprises a plurality of cooling channels. In some embodiments, the plasma mask is either the first electrode or the second electrode. In some embodiments, the walls of the plasma chamber are the second electrode.

In some embodiments, the plasma is initiated and maintained between bi-polar electrodes. In some embodiments, the plasma is initiated and maintained between tri-polar electrodes. In some embodiments, the plasma is initiated and maintained between an electrode and ground.

In some embodiments, the plasma mask comprises cooling channels. In some embodiments, the plasma chamber further comprises a vacuum. In some embodiments, a tray holding the substrate is the first electrode. In some embodiments, the at least one aperture has a different aspect ratio than a corresponding component on the substrate.

Disclosed herein are other embodiments including a system for plasma etching or ashing a coating on a substrate. The system includes a plasma chamber, a second electrode, a plasma source coupled to the plasma chamber, a substrate including a coating, and a plasma mask including at least one aperture. The plasma chamber includes a first electrode. The plasma mask is configured to cover the substrate while exposing selected surfaces of the substrate and coating through the at least one aperture. The first electrode and the second electrode are configured to initiate and maintain a plasma within the plasma chamber. The plasma source includes a gas. The plasma chamber further comprises a vacuum. The coating is a parylene. A cooling mechanism is coupled to the plasma chamber. The plasma mask comprises a thermal interface material.

Disclosed herein is a method. The method includes providing at least one substrate in a plasma chamber, the substrate including a coating, coupling a plasma mask to the substrate, the plasma mask comprising at least one aperture, generating a plasma within the plasma chamber between a first electrode and a second electrode, and etching or ashing the coating at the at least one aperture with the generated plasma.

In some embodiments, the method includes cycling between the etching or ashing and a cooling cycle. In some embodiments, the walls of the plasma chamber are the second electrode.

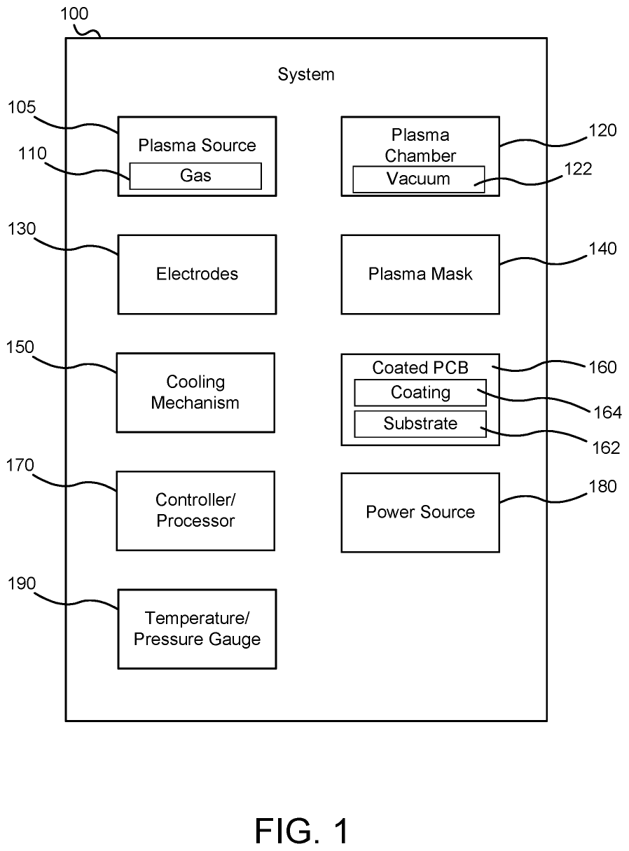

Referring to FIG. 1, a schematic diagram of a system for plasma etching or ashing a coating on a substrate 100 is shown. Although the system 100 is shown and described with certain components and functionality in the following paragraphs, other embodiments of the system 100 may include fewer or more components to implement less or more functionality.

The system 100 is configured to etch or ash a coating or film of a substrate or a plurality of substrates. The system 100 may utilize various components (not all necessary) to accomplish the etching or ashing of the substrate(s). Substrate may refer generally to PCBs, PCBAs, electronic components, electronic devices, etc. In some embodiments, the system 100 utilizes a plasma to selectively remove the coating or film from selected parts of the substrate. This may be accomplished utilizing a plasma mask to cover and protect portions of the substrate and coating from plasma etching or plasma ashing. As used herein, in some embodiments, plasma etching and plasma ashing are inclusive of each other. In some embodiments, plasma ashing refers to a process that is only used on organic materials while plasma etching refers to a process that is used only on non-organic materials.

Referring to FIG. 1, the system 100 includes a plasma source 105, including a gas 110 or gas source that is used for generation of the plasma. The system 100 includes a plasma chamber 120, which may include a vacuum 122, electrodes 130, plasma mask(s) 140, cooling mechanism(s) 150, controller(s)/processor(s) 170, temperature/pressure gauge(s) 190 (which encompasses various monitoring equipment to record accurate properties of the system 100.

In some embodiments, the system 100 includes a plasma source 105, including a gas 110 or gas source that is used for generation of the plasma. Various gases are contemplated for use and may depend on the thickness or type of coating, the type of plasma mask, the type of substrate, and/or the type of components on the substrate. Gases may include, but are not limited to CO₂, CF₄, C₃F₆, C₄F₈, CH₃F, SiF₄ SF₆, Ar, O₂, and H₂ or any of these gases mixed with oxygen, or any mixtures thereof. The gas composition and ratio may be optimized to provide the optimal coating removal with minimal or no damage to the underlying substrate and components. The plasma source 105 may be coupled to the plasma chamber 120. The plasma source 105 may be remote to the plasma chamber 120.

In some embodiments, the plasma source 105 distributes the gas 110 to the plasma chamber 120 for generation of the plasma within the plasma chamber 120. In some embodiments, the plasma is not generated in the plasma chamber 120 and is generated at the plasma source 105 remote from the plasma chamber 120. For examples where the plasma is generated in the plasma chamber 120, the gas 110 or gas mixture is flowed into the plasma chamber 120. Various flow rates are contemplated and may be optimized based on the type of gas, the thickness or type of coating, the type of plasma mask, the type of substrate, and/or the type of components on the substrate. An example of a flow rate is approximately 100 sccms (standard cubic centimeters per minute). Higher or slower flow rates are contemplated depending on the other factors including a range of 10-1000 sccms. The plasma may be created from a low flow/low pressure gas. Pressure may be on the order of 250 mTorr. Other pressures are contemplated depending on the other factors including a range of 25-2500 mTorr.

In some embodiments, the system 100 includes a plasma chamber 120. The plasma chamber 120 is a chamber that can maintain or generate properties including pressure, temperature, the distribution of plasma, and the storing or securing of substrates with coatings. The plasma chamber 120 may be various sizes and shapes that optimize the positioning of the substrates relative to the plasma generated. In many embodiments, the plasma chamber 120 is the chamber in which the plasma is initiated and maintained. In some embodiments, the plasma chamber 120 is a vacuum chamber. The plasma chamber 120 may include a vacuum 122 or vacuum source or other type of pressure regulation device that allows the plasma chamber 120 to maintain a vacuum or an optimal pressure during the plasma generation and coating removal. The physical structure may be cubic or elongated to allow for more efficient racking and loading of substrates. The plasma chamber 120 may be configured to allow horizontally stacked trays of substrates or vertically stacked substrates or another orientation.

The plasma chamber 120 may include, in some embodiments, an electrode 130. In some embodiments, the plasma chamber 120 may include two electrodes 130. In some embodiments, the plasma chamber 120 may include a plurality of electrodes 130. In some embodiments, the electrodes 130 may be external to the plasma chamber 130 as the plasma is generated remotely, either at the plasma source 105 or another location, and the plasma is directed into the plasma chamber 120. In many embodiments, the plasma is generated in the plasma chamber 120 by the one or more electrodes 130.

The system 100 may include separate standalone electrodes 130. In some embodiments, the various components of the system 100 may function as one or more of the electrodes 130. In some embodiments, there are two electrodes 130. They may be bi-polar electrodes 130 that function as positive and negative electrodes. In some embodiments, one of the electrodes 130 functions as ground. In some embodiments, the system includes tri-polar electrodes. In some embodiments, the plasma is initiated and maintained between positive, negative, and ground electrodes. In some embodiments, the plasma is initiated and maintained between positive, negative and float electrodes.

In some embodiments, the walls of the plasma chamber 120 function as one of the electrodes 130. In some embodiments, another part of the plasma chamber 120 functions as one of the electrodes 130. In some embodiments, the trays that may hold the substrates function as one of the electrodes 130. In some embodiments, the plasma mask 140 functions as one of the electrodes 130. In a nonlimiting example, the plasma may be initiated and maintained between the plasma masks 140 and the walls of the plasma chamber 120. Various combinations and permutations of the electrodes 130 are contemplated and are not described herein merely for the sake of brevity.

In some embodiments, the electrodes 130 are metal plates that impart voltage fields to the gases in the plasma chamber 120. In some embodiments, the electrodes 130 are horizontal in arrangement. In some embodiments, the electrodes 130 are vertical in arrangement. In some embodiments, the electrodes 130 are slanted or diagonal in arrangement. In some embodiments, the electrodes 130 include brackets. In some embodiments, the electrodes 130 include modular framing or fixtures that are each configured to hold at least one substrate. This could include securing mechanisms or just ridges or depressions configured to hold the individual substrates. In some embodiments, the electrodes 130 include cooling mechanisms such as a cooling device or cooling channels that are configured to cool the electrodes, the substrates, the plasma masks, or the chamber during off cycle. In order to not damage the substrates, some embodiments utilized cycling between plasma generation and a cooling cycled that allows the components, including the substrate, to not overheat and suffer irreparable damage.

The positioning and arrangement of the electrodes 130 may be non-standard and may be optimized to increase the etch rate or loading efficiency of the system 100. As already discussed, various configurations are contemplated such as all positive trays with negative walls, or positive loading trays with negative unused electrodes between. In some embodiments, the electrodes 130 and racking system can be combined to facilitate easy handling of the substrates and loading into the plasma chamber 120. In some embodiments, the electrodes 130 are removable from the plasma chamber. The plasma chamber 120 may include various electronics and components that allow for the connecting the electrodes to a power source 180 and allow for easy removal and replacement of the electrodes 130.

In some embodiments, the system 100 includes a power source 180. In some embodiments, the plasma is initiated and maintained using RF power. In some embodiments, the plasma is initiated and maintained using DC power. Various power sources are contemplated and may be coupled directly to the plasma chamber 120 or may be remote to generate the plasma. The system 100 may be configured to allow for varying power levels including, but not limited to, a range between 100 and 600 watts. Some embodiments might use power levels smaller or greater than the range described. The power levers may be cycled allowing for cooling in between. Cooling cycles allow for higher power utilization during etching cycles. The power level is optimized to result in optimal coating removal without overheating the substrates or damaging the components.

In some embodiments, the system 100 includes valves, temperature gauges, pressure gauges, and other gauges 190 generally to allow for monitoring of the system 100 and the various components of the system 100. The gauges 190 may be associated with the system 100 overall or may be associated particularly with an electrode 130, a plasma mask 140, a substrate 162, a cooling mechanism 150, or the plasma chamber 120 itself.

In some embodiments, the system 100 includes a controller 170 or a processor 170 that is configured to control the processing parameter or one or more of the components of the system 100. The controller 170 allows for the optimization of coating removal, allowing for the optimization of all the parameters discussed herein including, but not limited to, power, gas mixture, flow rate, pressure, temperature, etch time, cooling time, etc. The controller 170, in some embodiments, is configured to monitor the parameters or receive input of the parameters (which may include the coating thickness, temperature thresholds of the substrates, positioning of the substrates, positioning of the electrodes, etc.) and optimize the etch rate and etch times etc.

The system 100 may include one or more cooling mechanisms 150 that are configured to cool one or more components of the system, either during or after etching cycles. The cooling mechanisms 150 may be separate from the various components or may form part of the components themselves. In some embodiments, the cooling mechanism is incorporated into the plasma mask 140 or into the electrodes 130 or the plasma chamber 120. Various cooling mechanisms 150 are contemplated and may include, but are not limited to, water channels, liquid channels, piping, peltier cooling devices, or other thermoelectric cooling devices. The cooling mechanisms 150 may be controlled by the controller 170 and may have set pumping cycles that pump the liquid or other material through the channels or piping. The controller 170 may control pumping and purging cycles that are configured for optimal cooling. The cooling may occur in between plasma cycles. In some embodiments, the cooling is performed during the plasma cycles.

The system 100 may include coated substrates 160 which may be referred to as coated PCBs 160 or coated devices 160. The coated substrates 160 include a substrate 162 and a coating 164. As discussed herein, the substrate 162 may be any of a number of types of electronic devices generally or circuit boards generally. The coating 164 may refer to various types of coatings including, but not limited to, moisture resistant coatings, parylene, plasma, and ALD created films, etc. The plasma generated by the system 100 is configured to etch or ash the coating 164 at selected areas while not damaging the underlying substrate 162.

The selective removal of the coating 164 may be accomplished utilizing a plasma mask 140. The plasma mask 140 may be referred to simply as a mask or a physical mask, shadow mask, or stencil that is configured to cover certain portions of the coated substrate 160 while leaving other portions of the coated substrate 160 exposed. This may be accomplished to designed apertures, holes, or openings within the plasma mask 140. The plasma mask 140 serves a role of, among other things, protecting a coated substrate 160 from etching by plasma, while leaving exposed the areas where complete removal of parylene (or another thin film coating) is desired, such as on contact pads, USB, and other connectors.

The plasma mask 140 may be made of different materials or combinations of materials. In most cases, the plasma mask 140 is made of a material that will not be affected by the plasma, allowing for reuse of the plasma mask 140 for a plurality of coated substrates 160. In some embodiments, the plasma mask 140 is made of metal or combinations of metals. In some embodiments, the plasma mask 140 is made of plastic or combinations of plastics. In some embodiments, the plasma mask 140 is made of metal and plastic. In some embodiments, the plasma mask 140 is made of conductive material. In some embodiments, the plasma mask 140 is made of non-conductive material. The plasma mask 140 may be made of a combination of conductive and non-conductive material. Some examples of materials may include, but is not limited to, Ni, Al, stainless steel, ABS, nylon, glass filled ceramics, glass filled composites, ceramics, composites, or coated materials, glass fiber reinforced plastic (Durostone), glass mat composite (Durapol), or glass-bonded mica material (Mycalex), and other similar materials or combinations of materials.

In some embodiments, the plasma mask 140 includes cooling channels. The cooling channels may be added to a frame or fixture that holds the plasma mask 140 or may be integral with the plasma mask 140. As such, the material of plasma mask 140 may be selected based on thermal conductivity.

In some embodiments, the plasma mask 140 may include mechanical features or components that allow for the plasma mask 140 to be coupled to the substrate 162 or to multiple substrates 162. The coupling may be accomplished by a coupling mechanism. In some embodiments, coupling means direct contact between the plasma mask 140 and the substrate 162. In some embodiments, coupling means indirect contact with a defined gap between the plasma mask 140 and the substrate 162.

The plasma mask 140 includes one or more apertures, holes, or openings through which plasma generated in the plasma chamber 120 can be directed at the coating 164 on the substrate. The openings may be of any shape and size to accurately allow for the plasma to etch or ash the coating 164. The apertures or openings may have varying traits. In some embodiments, the edges of the openings contact the coating 164. In some embodiments, there is a small gap between the edges of the openings and the coating 164. In some embodiments, the apertures or openings have different aspect ratios. In some embodiments, the apertures or openings may have a smaller (or larger) opening than the size of the component on which the coating needs to be etched or ashed. In some embodiments, the apertures include bevels at the contact point of the apertures with the coated substrate 160.

In some embodiments, the plasma mask 140 includes multiple layers of varied material that provide various functions. In some embodiments, the plasma mask 140 includes an interface material that interfaces with the substrate. The interface material may be a thermal interface material or be a protective interface material such that the plasma mask 140 won't damage or scratch the coating 164 in the areas where the coating 164 is supposed to remain. In some embodiments, the plasma mask 140 includes three-dimensional features that better conform to the three-dimensional features of the substrate.

The plasma masks 140 may be manufactured in a variety of ways include through additive or subtractive methods. The plasma masks 140 may be manufactured through CNC machining, water jet cutting, laser cutting, 3D printing, lithography, xurography or any other similar methods for creating apertures in a material. The plasma masks 140 may be customized to fit the substrate 162.

All the features and description related to Figure may be applied to, but is not required, the other Figures. Additionally, the features and description related to the remaining Figures may be applied to, but is not required, all or some of the embodiments described with FIG. 1.

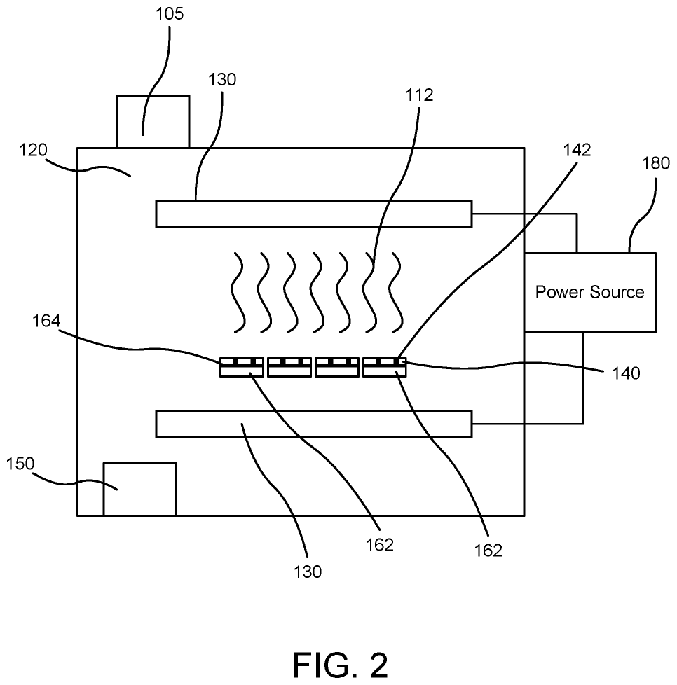

Referring to FIG. 2, a schematic diagram of a system for plasma etching or ashing a coating on a substrate is shown. As shown, the embodiment includes a power source 180 connected to two electrodes 130 within a plasma chamber 120. The two electrodes 130 initiate and maintain a plasma 112 within the plasma chamber 120. The system further includes a plasma source 105 and a cooling mechanism 150.

The generated plasma 112 is directed to or otherwise allowed to react with the coating 164 of the substrates 162. Each of the substrates 162 is coupled with a plasma mask 140, the plasma mask 140 including apertures 142. The apertures 142 allow for the plasma 112 to interact with the coating 164 in selected areas while protecting a remainder of the coating 164.

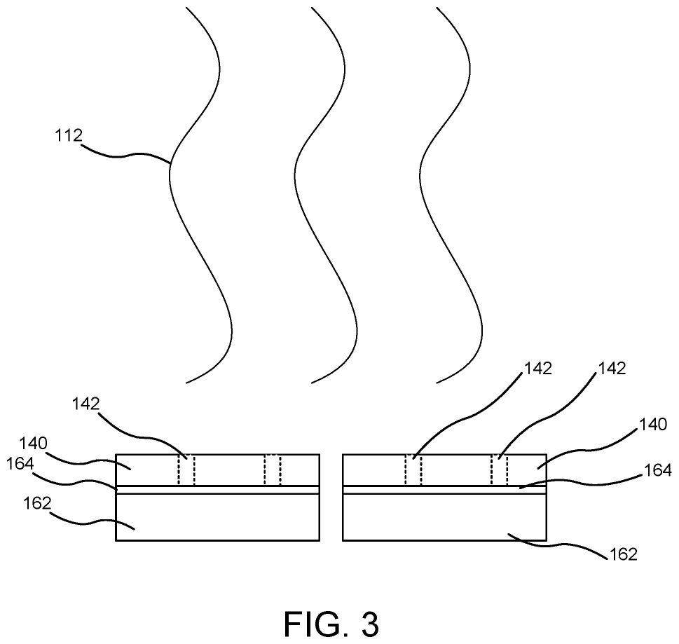

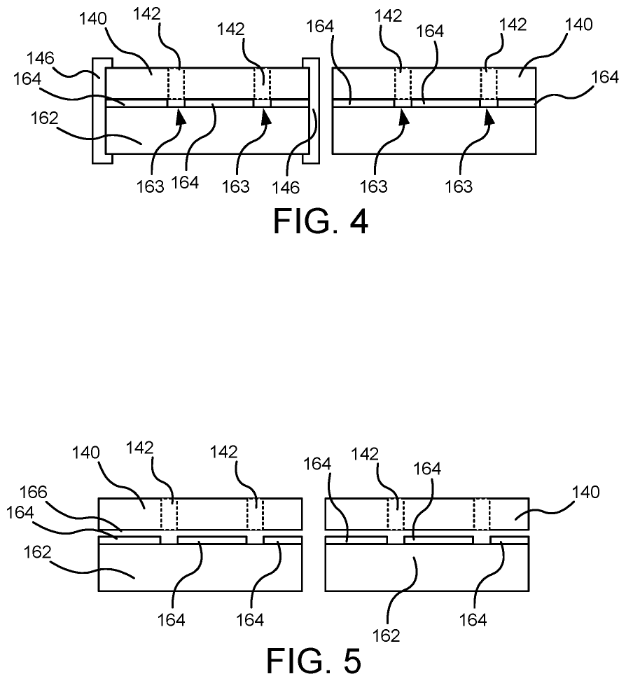

Referring to FIG. 3, an enlarged view depicts the substrates 162, coatings 164, plasma masks 140 and plasma 112. Referring to FIG. 4, two substrates 162 are shown, with the coating 164 removed from exposed areas 163. The exposed areas 163 are approximately the shape and size of the apertures 142 of the plasma masks 140. Also depicted is a coupling mechanism 146 that holds or otherwise secures the plasma mask 140 to the substrate 162.

FIG. 5 depicts another embodiment, similar to FIG. 4, but with a gap 166 between the plasma mask 140 and the coating 164 of the substrate 162. Although not shown, this gap could be accomplished through a coupling mechanism 146 that is configured to leave a gap 166 between the plasma mask 140 and the coating 164 of the substrate 162. As many plasma processes are line of sight, the gap 166 may not substantially affect the size and shape of the exposed surface 163 compared to the example of FIG. 4 while protecting the coating 164 from inadvertent damage from the plasma mask 140.

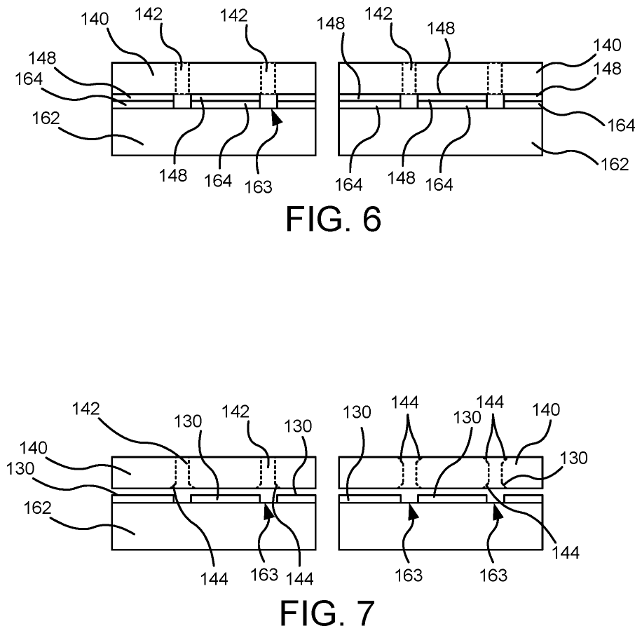

Referring to FIG. 6, the plasma mask may include an interface material 148 (such as a thermal interface material) that is between the plasma mask 140 and the coating 164. The interface material 148 may include apertures of the same or similar shape and size as the plasma mask 140. Additionally, FIG. 6 depicts the apertures 142 as slightly smaller than exposed areas 163.

Referring to FIG. 7, another embodiment is shown. In the illustrated embodiment, the apertures 142 include bevels 144. The bevels 144 may be on either or both sides of the plasma mask 140.

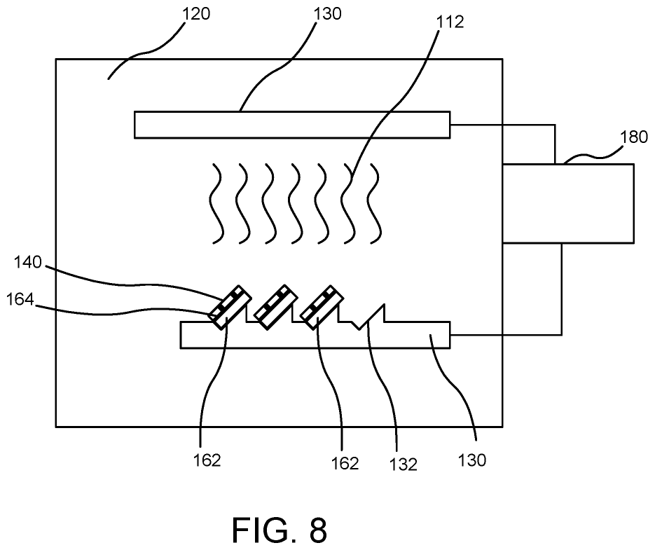

Referring now to FIG. 8, another embodiment of a system for plasma etching or ashing a coating on a substrate is shown. While similar to the embodiments associated with FIG. 2, the illustrated embodiment of FIG. 8 utilizes a tray that functions as one of the electrodes 130. The tray allows for the positioning and locating of the coated substrates and plasma masks 140 within the plasma chamber. The tray (or trays as multiple trays stacked are contemplated) may include features 132 that allow for orienting or holding or securing of the substrates 162. Although one implementation is shown, other implementations are contemplated that may orient or located the substrates in different ways. In some embodiments, the tray is not an electrode. In some embodiments, the plasma chamber 120 includes a rack or racking system. In some embodiments, the rack or racking system is internal to the plasma chamber 120. In some embodiments a plurality of trays can be placed on an internal rack of the plasma chamber 120. The rack allows for the stacking of trays in various orientations and configurations.

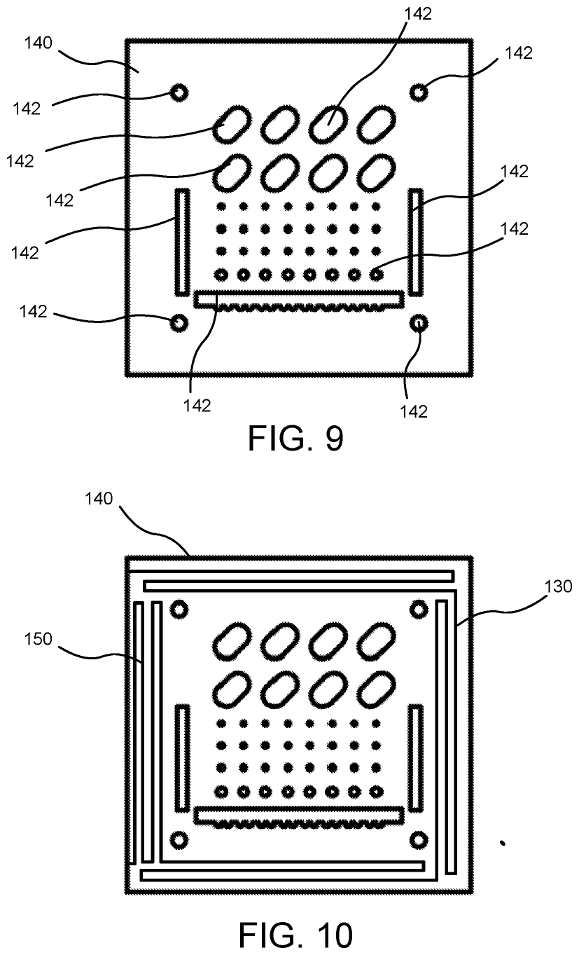

Referring now to FIG. 9, an embodiment of a plasma mask 140 is shown. The plasma mask 140 includes a plurality of apertures 142. As shown, the apertures 142 are different sizes and shapes. Additionally, the apertures 142 may have different aspect ratios with different thicknesses. The plasma mask may vary in thickness. Referring to FIG. 10, another embodiment is shown. Similar to the embodiment of FIG. 9, FIG. 10 also includes a cooling mechanism 150 (such as cooling channels) that are incorporated into the plasma mask 140. The channels of the cooling mechanism run along the edges of the plasma mask 140 back and forth, allowing for the funneling of a cooling liquid along the plasma mask 140. In some embodiments, the channels are located on the side of the plasma mask 140 that faces the plasma and away from the coating of the substrate. In other embodiments, the channels could be on the opposite side.

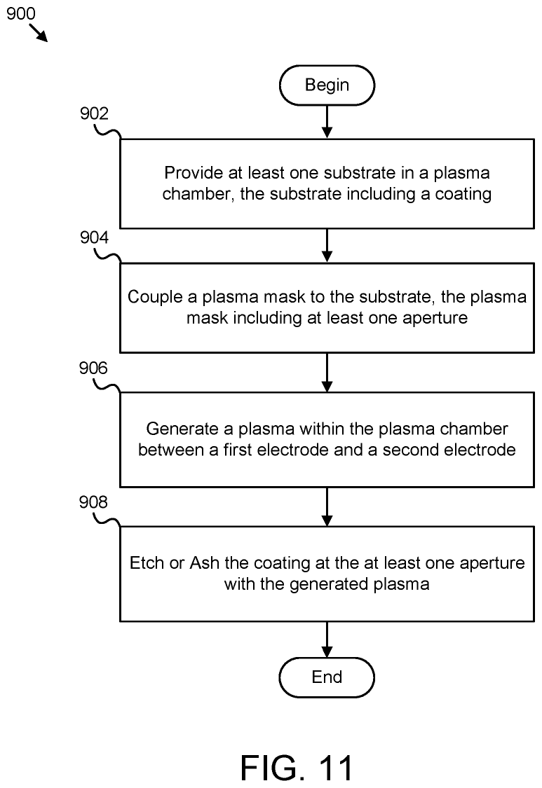

Referring to FIG. 11, a method 900 is disclosed. At block 902, the method 900 includes providing at least one substrate in a plasma chamber, the substrate including a coating. At block 904, the method 900 includes coupling a plasma mask to the substrate, the plasma mask comprising at least one aperture. At block 906, the method 900 includes generating a plasma within the plasma chamber between a first electrode and a second electrode. At block 908, the method 900 includes etching or ashing the coating at the at least one aperture with the generated plasma. The method 900 then ends.

In some embodiments, the method further includes cycling between the etching or ashing and a cooling cycle. The method may include cycling on and off the generating of the plasma. Where parylene or similar materials are used as the coating, the method may include chemically breaking down the polymer bonds of the coating. In some embodiments, the chemical breakdown occurs at the methyl bond first and at the benzene molecule during a ring opening process. The radical species of the plasma breads the bonds and allows for etching or ashing of the coating.

Embodiments of apparatuses are described herein that may include on some of the features and components of the systems described. Additionally, other methods of using and making the systems described herein are contemplated.

Although the foregoing disclosure provides many specifics, these should not be construed as limiting the scope of any of the ensuing claims. Other embodiments may be devised which do not depart from the scopes of the claims. Features from different embodiments may be employed in combination. The scope of each claim is, therefore, indicated and limited only by its plain language and the full scope of available legal equivalents to its elements.

Reference throughout this specification to features, advantages, or similar language does not imply that all of the features and advantages that may be realized with the subject matter of the present disclosure should be or are in any single embodiment. Rather, language referring to the features and advantages is understood to mean that a specific feature, advantage, or characteristic described in connection with an embodiment is included in at least one embodiment of the present disclosure. Thus, discussion of the features and advantages, and similar language, throughout this specification may, but do not necessarily, refer to the same embodiment.

In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

The present subject matter may be embodied in other specific forms without departing from its spirit or essential characteristics. The described embodiments are to be considered in all respects only as illustrative and not restrictive.

In the above description, specific details of various embodiments are provided. However, some embodiments may be practiced with less than all of these specific details. In other instances, certain methods, procedures, components, structures, and/or functions are described in no more detail than to enable the various embodiments of the invention, for the sake of brevity and clarity.

What is claimed:

1. A system for plasma etching/ashing a coating on a substrate, the system comprising:
a plasma chamber comprising a first electrode;
a second electrode, wherein the first electrode and the second electrode are configured to initiate and maintain a plasma within the plasma chamber;
a plasma source coupled to the plasma chamber, the plasma source comprising a gas;
a substrate comprising a coating; and
a plasma mask comprising at least one aperture, the plasma mask configured to cover the substrate while exposing selected surfaces of the substrate and coating through the at least one aperture.

2. The system of claim 1, wherein the coating is a parylene coating and wherein the system further comprises a power source coupled to the first and second electrodes.

3. The system of claim 1, further comprising a cooling mechanism coupled to the plasma chamber.

4. The system of claim 1, wherein the plasma mask comprises a thermal interface material.

5. The system of claim 1, wherein the plasma mask comprises a bevel at the at least one aperture.

6. The system of claim 1, wherein the plasma mask is mechanically coupled to the substrate.

7. The system of claim 1, wherein at least one of the first electrode and the second electrode comprises at least one cooling channel.

8. The system of claim 1, wherein at least one of the first electrode and the second electrode comprises a plurality of cooling channels.

9. The system of claim 1, wherein the plasma mask is either the first electrode or the second electrode.

10. The system of claim 1, wherein the plasma is initiated and maintained between bi-polar electrodes.

11. The system of claim 1, wherein the plasma is initiated and maintained between tri-polar electrodes.

12. The system of claim 1, wherein the plasma mask comprises cooling channels.

13. The system of claim 1, wherein the plasma chamber further comprises a vacuum.

14. The system of claim 1, wherein walls of the plasma chamber are the second electrode.

15. The system of claim 1, wherein a tray holding the substrate is the first electrode.

16. The system of claim 1, wherein the at least one aperture has a different aspect ratio than a corresponding component on the substrate.

17. A system for plasma etching/ashing a coating on a substrate, the system comprising:
a plasma chamber comprising a first electrode, the plasma chamber further comprising a vacuum;
a second electrode, wherein the first electrode and the second electrode are configured to initiate and maintain a plasma within the plasma chamber;
a plasma source coupled to the plasma chamber, the plasma source comprising a gas;
a substrate comprising a coating, wherein the coating is a parylene; and
a plasma mask comprising at least one aperture, the plasma mask configured to cover the substrate while exposing selected surfaces of the substrate through the at least one aperture, wherein the plasma mask comprises an interface material, wherein the plasma mask is mechanically coupled to the substrate.

18. A method comprising:
providing at least one substrate in a plasma chamber, the substrate including a coating;
coupling a plasma mask to the substrate, the plasma mask comprising at least one aperture;
generating a plasma within the plasma chamber between a first electrode and a second electrode; and
etching or ashing the coating at the at least one aperture with the generated plasma.

19. The method of claim 18, further comprising cycling between the etching or ashing and a cooling cycle.

20. The method of claim 18, wherein walls of the plasma chamber are the second electrode.
